(19) United States
(12) Patent Application Publication
(10) Pub. No.: US 2012/0320697 A1
(43) Pub. Date: Dec. 20, 2012

(54) NON-VOLATILE SEMICONDUCTOR MEMORY DEVICE

(75) Inventor: Yasushi NAGADOMI, Yokohama-shi (JP)

(73) Assignee: Kabushiki Kaisha Toshiba, Tokyo (JP)

(21) Appl. No.: 13/492,174

(22) Filed: Jun. 8, 2012

(30) Foreign Application Priority Data
Jun. 14, 2011 (JP) P2011-132428

(51) Int. Cl. G11C 7/00

(52) U.S. Cl. 365/218; 365/189.011

(57) ABSTRACT

A non-volatile semiconductor memory device includes a plurality of memory strings, a plurality of memory blocks, a plurality of source-lines, and a control circuit. Each of the memory strings includes a plurality of stacked memory transistors. Each of the memory blocks includes the memory strings. Each of the source-lines are connected to the respective memory strings. The control circuit is configured to output signals to a switch circuit depending on the types of operations for the memory transistors. The switch circuit is capable of connecting the plurality of source-lines electrically and commonly depending on the signals.

### CROSS-REFERENCE TO RELATED APPLICATIONS

This application is based upon and claims the benefit of priority from the prior Japanese Patent Application No. 2011-132428, filed on Jun. 14, 2011, the entire contents of which are incorporated herein by reference.

### FIELD

The embodiments described herein relate to a non-volatile semiconductor memory device capable of electrically rewriting data.

### BACKGROUND

To improve the bit density of a non-volatile semiconductor memory device such as a NAND flash memory, stacked memory cells have recently drawn attention as the microfabrication technology is approaching its limit. One proposed technology is a stacked NAND flash memory including a vertical transistor as a memory transistor. The stacked NAND flash memory includes a pluraity of memory strings and select transistors provided at both ends of each memory string. Each memory string includes a plurality of memory transistors connected in series in the stacking direction. A source of one select transistor is connected to a source-line. A drain of the other select transistor is connected to a bit-line.

In the above stacked NAND flash memory, an erase operation can be selectively performed for each set of memory strings (memory blocks) commonly connected to one source-line by controlling the voltages of the source-lines by a driver. Therefore, reducing the number of memory strings connected to one source-line can reduce a performable unit of the erase operation. Unfortunately, the reduced number of memory strings connected to one source-line results in a smaller line width of each source-line and larger wiring resistance of the source-lines. A read operation is performed by sensing current flows from the bit-lines to the source-lines. Therefore, the larger wiring resistance of the source-lines may raise the voltages of the source-lines above the originally expected voltages, thereby resulting in an inaccurate read operation.

### BRIEF DESCRIPTION OF THE DRAWINGS

FIG. 1 shows a memory cell array MA and a control circuit CC of a non-volatile semiconductor memory device according to a first embodiment.

FIG. 2 is a perspective view of the stacked structure of the memory cell array MA according to the first embodiment.

FIG. 3 is a cross-sectional view of the stacked structure of the memory cell array MA according to the first embodiment.

FIG. 4 is a top view of the word-line conductive layer 41a in the first embodiment.

FIG. 5 illustrates the connection relationship between the source-lines SL(1) to SL(6) and the control circuit CC in the first embodiment.

FIG. 6 is a cross-sectional view along the A-A′ in FIG. 5.

FIG. 7 is a cross-sectional view along the B-B′ in FIG. 5.

FIG. 8 illustrates the read operation according to the first embodiment.

FIG. 9 illustrates the write operation according to the first embodiment.

FIG. 10 illustrates the erase operation according to the first embodiment.

FIG. 11 illustrates the connection relationship between the source-lines SL(1) to SL(6) and the control circuit CC in a second embodiment.

FIG. 12 illustrates the connection relationship between the source-lines SL(1) to SL(6) and the control circuit CC in a third embodiment.

FIG. 13 is a cross-sectional view along the A-A′ in FIG. 12.

FIG. 14 illustrates the connection relationship between the source-lines SL(1) to SL(6) and the control circuit CC in a fourth embodiment.

FIG. 15 is a cross-sectional view along the A-A′ in FIG. 14.

FIG. 16 illustrates the connection relationship between the source-lines SL(1) to SL(6) and the control circuit CC in a fifth embodiment.

FIG. 17 is a circuit diagram of the gate control circuit GC(1) in the fifth embodiment.

FIG. 18 is a perspective view of the stacked structure of the memory cell array MA in another embodiment.

### DETAILED DESCRIPTION

A non-volatile semiconductor memory device according to an aspect includes a plurality of memory strings, a plurality of memory blocks, a plurality of source-lines, and a control circuit. Each of the memory strings includes a plurality of stacked memory transistors. Each of the memory blocks includes the memory strings. Each of the source-lines are connected to the respective memory strings. The control circuit is configured to output signals to a switch circuit depending on the types of operations for the memory transistors. The switch circuit is capable of connecting the plurality of source-lines electrically and commonly depending on the signals.

Referring now to the drawings, embodiments of a non-volatile semiconductor memory device will be described below.

### First Embodiment

### [Schematic Configuration]

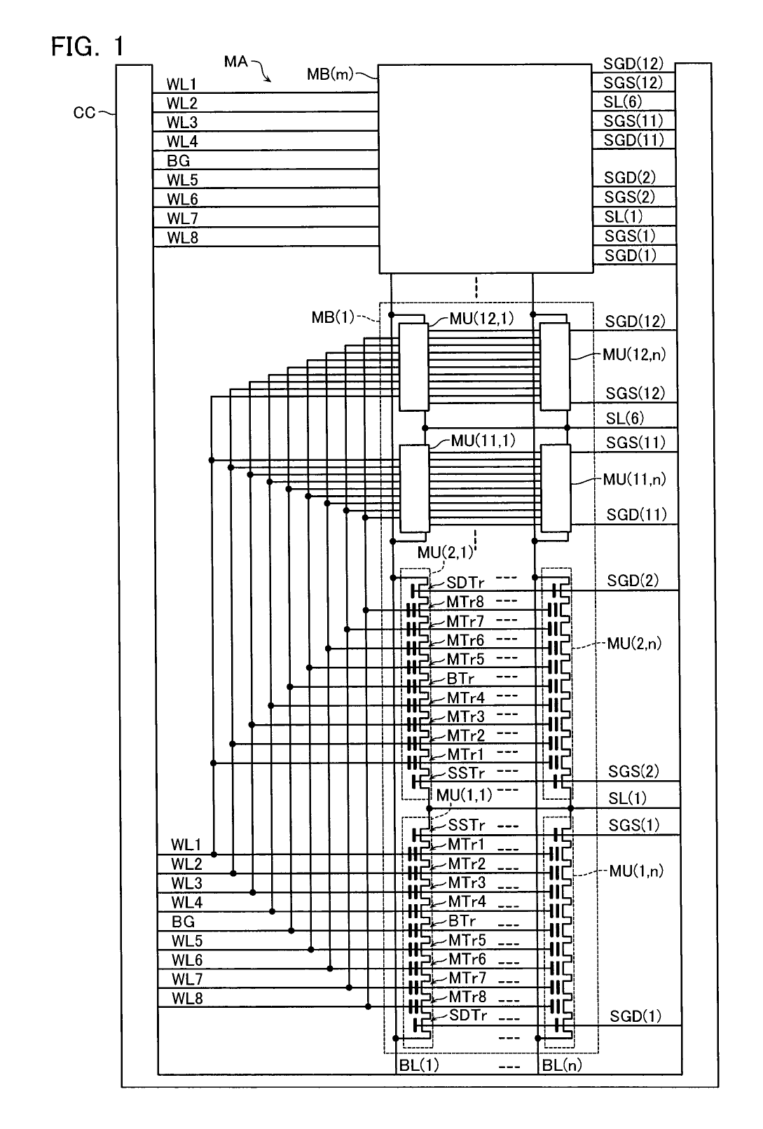

Referring first to FIG. 1, a schematic configuration of a non-volatile semiconductor memory device according to a first embodiment will be described. With reference to FIG. 1, the non-volatile semiconductor memory device according to the first embodiment includes a memory cell array MA and a control circuit CC. The control circuit CC controls signals supplied to the memory cell array 1.

With reference to FIG. 1, the memory cell array MA includes m memory blocks MB(1), . . . , MB(m). Note that all memory blocks MB(1), . . . , MB(m) may hereinafter be collectively described as a memory block MB. Each memory block MB includes memory units MU(1, 1) to MU (12, n) disposed in an n-row and 12-column matrix. The n-rows and 12 columns are merely an example, and the invention is not limited thereto. Note that all memory units MU(1, 1) to MU (12, n) may hereinafter be collectively described as a memory unit MU.

The memory unit MU includes a memory string MS, a source-side select transistor SSTr, and a drain-side select transistor SDTr.

With reference to FIG. 1, the memory string MS includes memory transistors MTr1 to MTr8 and a back gate transistor BTr connected in series. The memory transistors MTr1 to MTr4 and MTr5 to MTr8 are connected in series, respectively. The back gate transistor BTr is connected between the memory transistor MTr4 and the memory transistor MTr5.

The memory transistors MTr1 to MTr8 accumulate charges in their charge accumulation layers, thereby changing their threshold voltages, and hold data that corresponds to the threshold voltages. The back gate transistor BTr is rendered conductive when at least the memory string MS is selected as the operation target.

In each of the memory blocks MB(1) to MB(m), gates of the memory transistors MTr1 to MTr8 arranged in n-rows and columns are commonly connected to the respective word-lines WL1 to WL8. Gates of the back gate transistors BTr arranged in n-rows and 12 columns are commonly connected to a back gate line BG.

The source-side select transistor SSTr has a drain connected to the source of the memory transistor MTr1.

Sources of the source-side select transistors SSTr located in the first and second columns of the memory block MB are commonly connected to a source-line SL(1). The same holds true for the third or more columns. For example, sources of the source-side select transistors SSTr located in the eleventh and twelfth columns of the memory block MB are commonly connected to a source-line SL(6). All source-lines SL(1) to SL(6) may hereinafter be collectively described as a source-line SL.

Here, the control circuit CC in the first embodiment performs, depending on the various operations (a write operation, a read operation, and an erase operation), a control of commonly connecting the source-lines SL(1) to SL(6). The configuration of the control circuit CC and the control will be described in more detail below.

Further, in the first column of the memory block MB, the source-side select transistors SSTr have gates connected to a source-side select gate line SGS (1). The same holds true for the second or more columns. For example, in the twelfth column of the memory block MB, the source-side select transistors SSTr have gates connected to a source-side select gate line SGS (12). All source-side select gate lines SGS(1) to SGS (12) may hereinafter be collectively described as a source-side select gate line SGS.

The drain-side select transistor SDTr has a source connected to the drain of the memory transistor MTr8. Drains of the drain-side select transistors SDTr located in the first row of the memory block MB are commonly connected to a bit-line BL (1). The same holds true for the second or more rows. For example, drains of the drain-side select transistors SDTr located in the n-th row of the memory block MB are commonly connected to a bit-line BL(n). The bit-lines BL(1) to BL(n) are each formed over the memory blocks MB. All bit-lines BL(1) to BL(n) may hereinafter be collectively described as a bit-line BL.

In the first column of the memory block MB, the drain-side select transistors SDTr have gates connected to a drain-side select gate line SGD (1). The same holds true for the second or more columns. For example, in the twelfth column of the memory block MB, the drain-side select transistor SDTrs have gates connected to a drain-side select gate line SGD (12). All drain-side select gate lines SGD (1) to SGD (12) may hereinafter be collectively described as a drain-side select gate line SGD.

### [Stacked Structure of Memory Block MB]

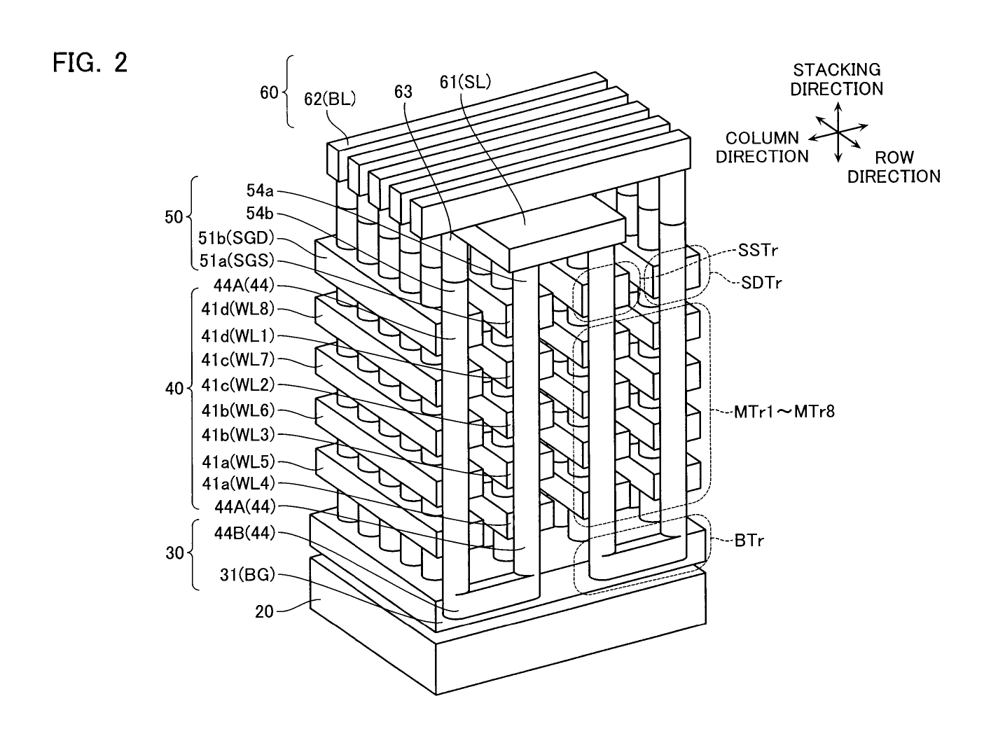

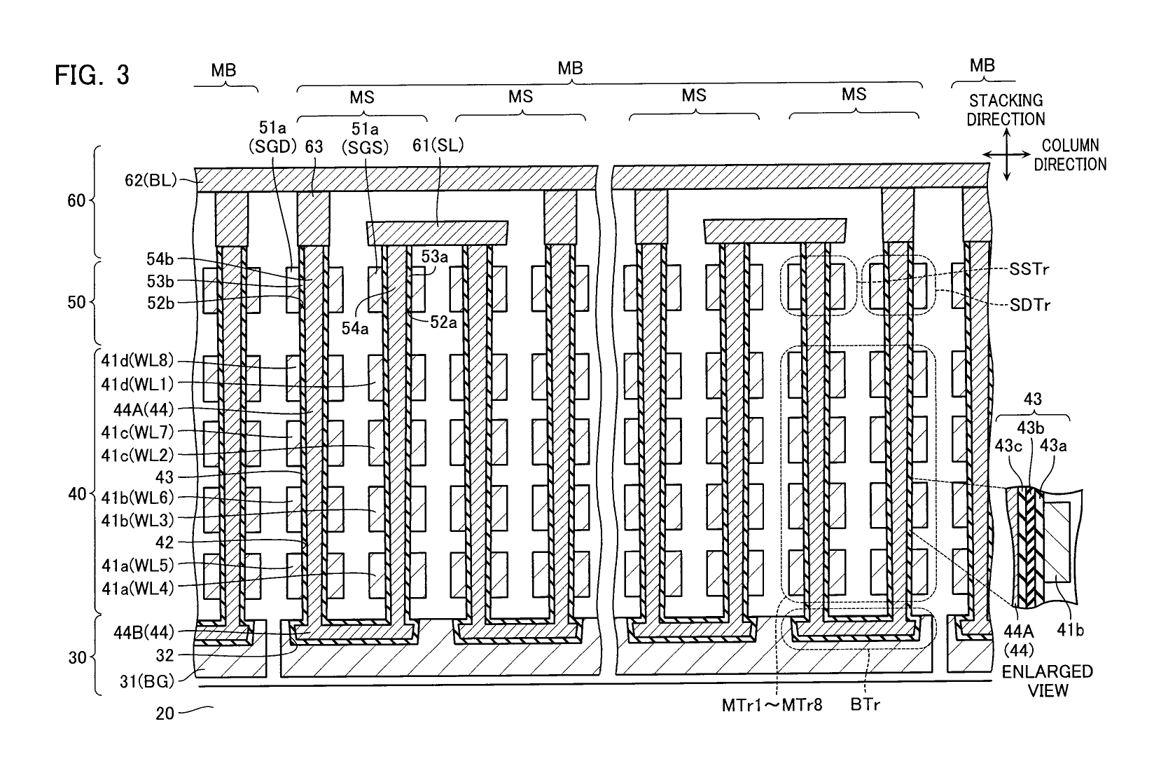

Referring now to FIG. 2 and FIG. 3, the stacked structure of the memory block MB according to the first embodiment will be described. FIG. 2 is a perspective view of the memory block MB. FIG. 3 is a cross-sectional view of the memory block MB. Note that FIG. 2 shows a portion of the memory block MB as a representative thereof. The entire memory block MB has a structure in which the structure shown in FIG. 2 is repeatedly formed in the column and row directions.

With reference to FIG. 2 and FIG. 3, the memory block MB includes a back gate layer 30, a memory layer 40, a select transistor layer 50, and a wiring layer 60, which are sequentially stacked on a substrate 20. The back gate layer 30 functions as the back gate transistors BTr. The memory layer 40 functions as the memory transistors MTr1 to MTr8. The select transistor layer 50 functions as the drain-side select transistors SDTr and the source-side select transistors SSTr. The wiring layer 60 functions as the source-lines SL and the bit-lines BL.

With reference to FIG. 2 and FIG. 3, the back gate layer 30 includes a back gate conductive layer 31. The back gate conductive layer 31 functions as the back gate line BG and as the gates of the back gate transistors BTr. The back gate conductive layer 31 is formed two-dimensionally, extending like a plate, in the row and column directions parallel to the substrate 20. The back gate conductive layer 31 is made of a material such as polysilicon (poly-Si).

With reference to FIG. 3, the back gate layer 30 includes a memory gate insulating layer 43 and a joining semiconductor layer 44B. The memory gate insulating layer 43 is provided between the joining semiconductor layer 44B and the back gate conductive layer 31. The joining semiconductor layer 44B functions as a body (channel) of the back gate transistor BTr. The joining semiconductor layer 44B is formed trimming the back gate conductive layer 31. The joining semiconductor layers 44B are formed in a generally rectangular shape having a longitudinal direction in the column direction when viewed in top plan view. The joining semiconductor layer 44B is formed in a matrix in the row and column directions in one memory block MB. The joining semiconductor layer 44B is made of a material such as polysilicon (poly-Si).

With reference to FIG. 2 and FIG. 3, the memory layer 40 is formed in a layer above the back gate layer 30. The memory layer 40 includes four word-line conductive layers 41a to 41d. The word-line conductive layer 41a functions as word-lines WL4 and as the gates of the memory transistors MTr4 . The word-line conductive layer 41a also functions as the word-lines WL5 and as the gates of the memory transistors MTr5. Likewise, the word-line conductive layers 41b to 41d function as the respective word-lines WL1 to WL3 and as the respective gates of the memory transistors MTr1 to MTr3. The word-line conductive layers 41b to 41d also function as the respective word-lines WL6 to WL8 and as the respective gates of the memory transistors MTr6 to MTr8.

The word-line conductive layers 41a to 41d are stacked having an interlayer insulating layer (not shown) between each layer. The word-line conductive layers 41a to 41d are formed at a certain pitch in the column direction and as extending in the row direction (a direction perpendicular the plane of FIG. 3) as the longitudinal direction. The word-line conductive layers 41a to 41d are made of a material such as polysilicon (poly-Si).

With reference to FIG. 3, the memory layer 40 includes a memory gate insulating layer 43 and a columnar semiconductor layer 44A. The memory gate insulating layer 43 is provided between the columnar semiconductor layer 44A and the word-line conductive layers 41a to 41d. The columnar semiconductor layer 44A functions as the bodies (channels) of the memory transistors MTr1 to MTr8.

The memory gate insulating layer 43 includes, from a side surface side of each of the word-line conductive layers 41a to 41d to a side of the memory columnar semiconductor layer 44, a block insulating layer 43a, a charge accumulation layer 43b, and a tunnel insulating layer 43c. The charge accumulation layer 43b is adapted to be capable of accumulating charges.

The block insulating layer 43a is formed on the side surfaces of the word-line conductive layers 41a to 41d with a predetermined thickness. The charge accumulation layer 43b is formed on a side surface of the block insulating layer 43a with a predetermined thickness. The tunnel insulating layer 43c is formed on a side surface of the charge accumulation layer 43b with a predetermined thickness. The block insulating layer 43a and the tunnel insulating layer 43c are made of a material such as silicon dioxide (SiO2). The charge accumulation layer 43b is made of a material such as silicon nitride (SiN).

The columnar semiconductor layer 44A is formed passing through the word-line conductive layers 41a to 41d and an interlayer insulating layer (not shown). The columnar semiconductor layer 44A extends in a direction perpendicular to the substrate 20. A pair of columnar semiconductor layers 44A are formed aligning the vicinity of the end portions of the joining semiconductor layer 44B in the column direction. The columnar semiconductor layer 44A is made of a material such as polysilicon (poly-Si).

In the above back gate layer 30 and memory layer 40, the pair of columnar semiconductor layers 44A and the joining semiconductor layer 44B joining lower ends of the columnar semiconductor layers 44A form the memory semiconductor layer 44 functioning as a body (channel) of the memory string MS.

The memory semiconductor layer 44 is formed in a U shape when viewed in the row direction.

The above back gate layer 30 has, in other words, a configuration in which the back gate conductive layer 31 is formed surrounding the side surface and bottom surface of the joining semiconductor layer 44B via the memory gate insulating layer 43. Further, the above described memory layer 40 has, in other words, a configuration in which the word-line conductive layers 41a to 41d are formed surrounding the side surface of the columnar semiconductor layer 44A via the memory gate insulating layer 43.

With reference to FIG. 2 and FIG. 3, the select transistor layer 50 includes a source-side conductive layer 51a and a drain-side conductive layer 51b. The source-side conductive layer 51a functions as the source-side select gate line SGS and as the gate of the source-side select transistor SSTr. The drain-side conductive layer 51b functions as the drain-side select gate line SGD and as the gate of the drain-side select transistor SDTr.

The source-side conductive layer 51a is formed in a layer above one of the first columnar semiconductor layers 44A included in the memory semiconductor layer 44. The drain-side conductive layer 51b is formed in the same layer as the source-side conductive layer 51a. The layer 51b is formed in a layer above the other one of the columnar semiconductor layers 44A included in the memory semiconductor layer 44. The source-side conductive layers 51a and the drain-side conductive layers 51b are formed at a predetermined pitch in the column direction and as extending in the row direction. The source-side conductive layer 51a and the drain-side conductive layer 51b are made of a material such as polysilicon (poly-Si). With reference to FIG. 3, the select transistor layer includes a source-side gate insulating layer 53a, a source-side columnar semiconductor layer 54a, a drain-side gate insulating layer 53b, and a drain-side columnar semiconductor layer 54b. The source-side columnar semiconductor layer 54a functions as a body (channel) of the source-side select transistor SSTr. The drain-side columnar semiconductor layer 54b functions as a body (channel) of the drain-side select transistor SDTr.

The source-side gate insulating layer 53a is provided between the source-side conductive layer 51a and the source-side columnar semiconductor layer 54a. The source-side columnar semiconductor layer 54a is formed passing through the source-side conductive layer 51a. The source-side columnar semiconductor layer 54a is connected to the side surface of the source-side gate insulating layer 53a and a top surface of one of the pair of columnar semiconductor layers 44A. The source-side columnar semiconductor layer 54a is formed in a columnar shape extending in a direction perpendicular to the substrate 20. The source-side columnar semiconductor layer 54a is made of a material such as polysilicon(poly-Si).

The drain-side gate insulating layer 53b is provided between the drain-side conductive layer 51b and the drain-side columnar semiconductor layer 54b. The drain-side columnar semiconductor layer 54b is formed passing through the drain-side conductive layer 51b. The drain-side columnar semiconductor layer 54b is connected to the side surface of the drain-side gate insulating layer 53b and a top surface of the other one of the pair of columnar semiconductor layers 44A. The layer drain-side columnar semiconductor 54b is formed in a columnar shape extending in a direction perpendicular to the substrate 20. The drain-side columnar semiconductor layer 54b is made of a material such as polysilicon (poly-Si).

With reference to FIG. 2 and FIG. 3, the wiring layer 60 includes a source-line layer 61, a bit-line layer 62, and a plug layer 63. The source-line layer 61 functions as the source-lines SL. The bit-line layer 62 functions as the bit-lines BL.

The source-line layer 61 is formed in contact with a top surface of the source-side columnar semiconductor layer 54a and as extending in the row direction. The bit-line layer 62 is formed in contact with a top surface of the drain-side columnar semiconductor layer 54b via the plug layer 63 and as extending in the column direction. The source-line layer 61, the bit-line layer 62, and the plug layer 63 are made of metal material such as tungsten.

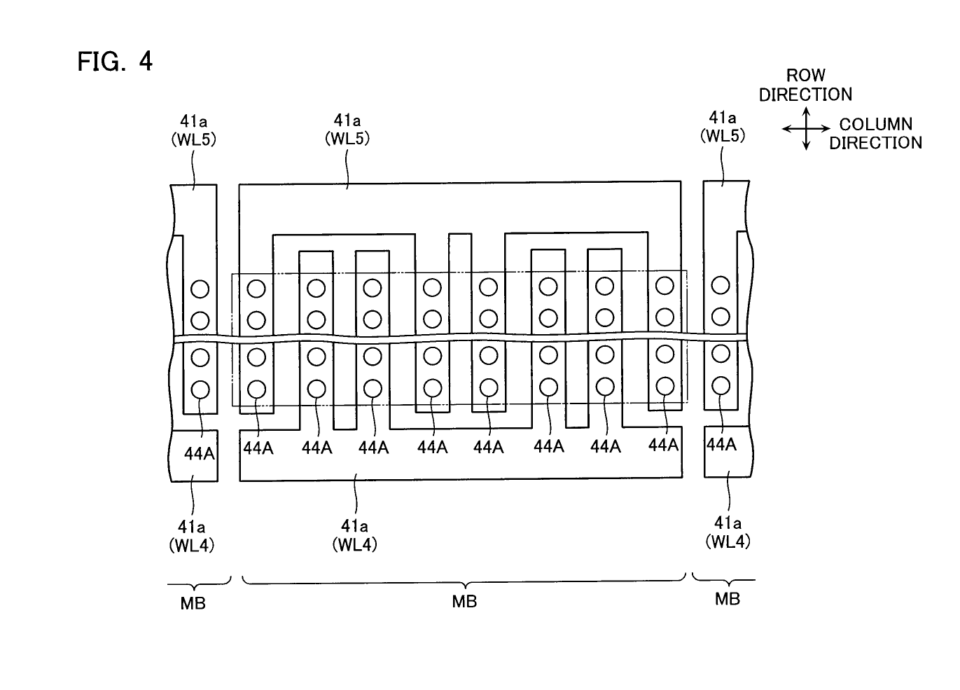

Referring now to FIG. 4, the shape of the word-line conductive layer 41a will be described in more detail. Note that the word-line conductive layers 41b to 41d have similar shapes to the word-line conductive layer 41a and thus their description is omitted here.

With reference to FIG. 4, a pair of word-line conductive layers 41a are provided in each memory block MB. The pair of word-line conductive layers 41a are disposed in a comb teeth shape in which the layers 41a engage with each other horizontally when viewed in top plan view.

### [Connection Relationship of Source-Line SL]

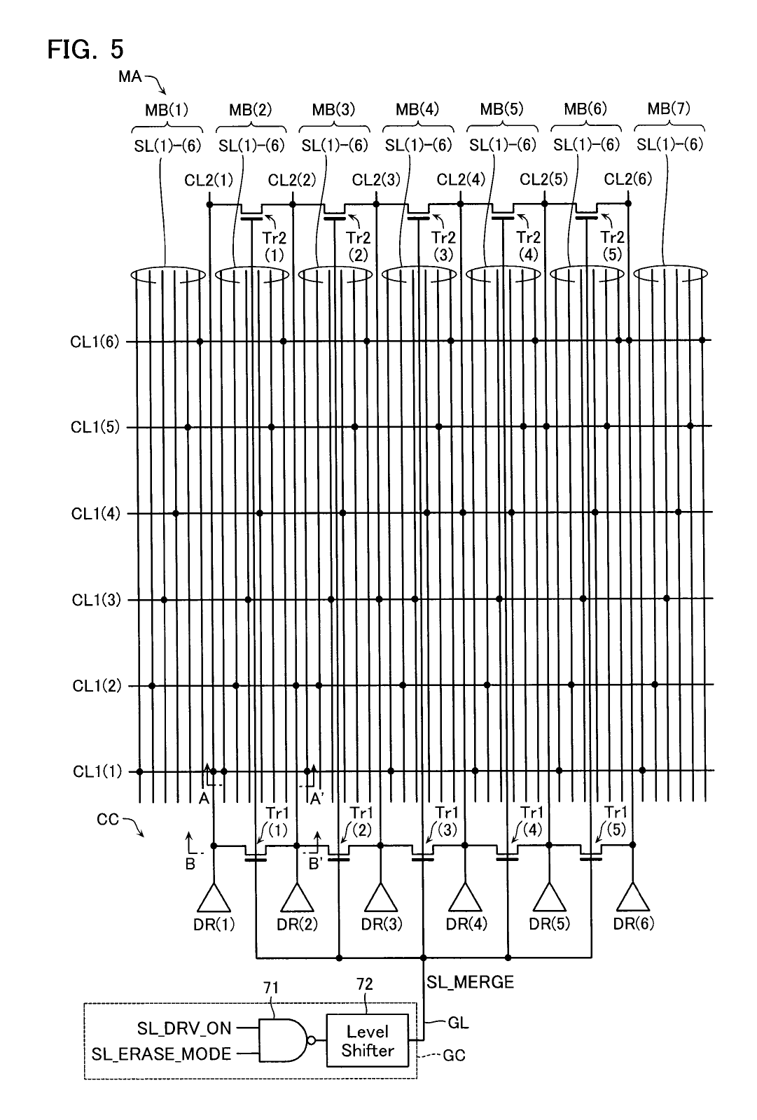

Referring now to FIG. 5, connection relationship between the source-lines SL(1) to SL(6) and the control circuit CC will be described. In FIG. 5, the memory cell array MA includes, by way of example, seven memory blocks MB(1) to MB(7). With reference to FIG. 5, the memory cell array MA includes six source-lines SL(1) to SL(6) for each set of memory blocks MB (1) to MB (7). Further, the memory cell array MA includes six first common wiring lines CL1(1) to CL1(6) and six second common wiring lines CL2(1) to CL2(6).

Each of the first common wiring lines CL1(1) to CL1(6) is connected to the respective source-lines SL(1) to SL(6) in the memory blocks MB. Each of the second common wiring lines CL2(1) to CL2(6) is connected to the respective first common wiring lines CL1(1) to CL1(6). Note that as will be described in more detail below, the first common wiring lines CL1(1) to CL1(6) are provided in a layer above the source-lines SL(1) to SL(6), and the second common wiring lines CL2 (1) to CL2 (6) are provided in a layer above the first common wiring lines CL1(1) to CL1(6).

With reference to FIG. 5, the control circuit CC includes six drivers DR(1) to DR(6), transistors Tr1(1) to Tr1 (5) and Tr2 (1) to Tr2 (5) (switch circuit) , a gate line GL, and a gate control circuit GC. The drivers DR(1) to DR(6) are connected to the first ends of the second common wiring lines CL2 (1) to CL2 (6) and control the voltages thereof. All transistors Tr1(1) to Tr1(5) and Tr2(1) to Tr2(5) may hereinafter be collectively described as transistors Tr1 and Tr2, respectively.

The transistors Tr1 and Tr2 have thicker gate oxide films than the source-side select transistors SSTr(the drain-side select transistors SDTr). The transistors Tr1 and Tr2 are designed to have a high breakdown voltage. The transistor Tr1 is formed closer to the drivers DR(1) to DR(6) than the transistor Tr2 is. The transistor Tr1 is provided on the first end side of the second common wiring lines CL2 (1) to CL2(6). The transistor Tr2 is provided on the second end side of the second common wiring lines CL2(1) to CL2(6).

The transistors Tr1(1) and Tr2(1) are provided between the second common wiring line CL2(1) and the second common wiring line CL2 (2). The transistors Tr1(2) and Tr2 (2) are provided between the second common wiring line CL2 (2) and the second common wiring line CL2 (3). The transistors Tr1 (3) and Tr2 (3) are provided between the second common wiring line CL2 (3) and the second common wiring line CL2 (4). The transistors Tr1 (4) and Tr2 (4) are provided between the second common wiring line CL2 (4) and the second common wiring line CL2 (5). The transistors Tr1 (5) and Tr2 (5) are provided between the second common wiring line CL2 (5) and the second common wiring line CL2 (6).

Further, the gates of the transistors Tr1 and Tr2 are commonly supplied with a signal SL_MERGE from the gate control circuit GC via the gate line GL. The gates are rendered conductive or non-conductive in response to the signal. The signal SL_MERGE is set to “L” when the drivers DR (1) to DR (6) are driven and the erase operation is performed, and otherwise to “H.” Therefore, the transistors Tr1 and Tr2 are rendered non-conductive in the erase operation and are rendered conductive in the other operations, than the erase operation, i.e., the read and write operations.

By controlling the transistors Tr1 and Tr2 to be non-conductive as described above, the source-lines SL (1) to SL (6) are not commonly connected in the erase operation. In other words, the voltages applied to the source-lines SL (1) to SL (6) may be independently controlled. Thus, in the erase operation, different voltages may be set to the respective source-lines SL (1) to SL (6). In the first embodiment, therefore, in the erase operation, the erase operation may be performed for each set of memory units MU (memory strings MS) connected to the respective source-lines SL(1) to SL(6). In other words, in the first embodiment, the performable unit of the erase operation may be the memory unit MU smaller than the memory block MB.

Further, by controlling the transistors Tr1 and Tr2 to be conductive as described above, all source-lines SL(1) to SL(6) are commonly connected in the read operation. Here, all source-lines SL(1) to SL(6) are applied with the same voltage in the read operation as described below, so the source-lines SL (1) to SL (6) maybe commonly connected without any problem in the read operation. In the first embodiment, therefore, in the read operation, the commonly connected source-lines SL(1) to SL(6) may reduce their wiring resistance, thereby performing the read operation correctly.

Further, it is thus not necessary to enhance the driver's drive capability or increase the source-line width. Therefore, in the first embodiment, the increase of the occupied area of the non-volatile semiconductor memory device may be suppressed.

Further, by controlling the transistors Tr1 and Tr2 to be conductive as described above, the source-lines SL(1) to SL(6) are commonly connected in the write operation. Here, all source-lines SL(1) to SL(6) are applied with the same voltage in the write operation as described below, so the source-lines SL (1) to SL (6) maybe commonly connected without any problem in the write operation. In the first embodiment, therefore, in the write operation, the commonly connected source-lines SL(1) to SL(6) may reduce their wiring resistance.

The configuration of the gate control circuit GC will now be described. With reference to FIG. 5, the gate control circuit GC includes an NAND circuit 71 and a level shifter 72. The NAND circuit 71 has a first end input terminal supplied with a signal SL_DRV_ON and a second end input terminal supplied with a signal SL_ERASE_MODE. The NAND circuit 71 outputs, in response to the supplied signal, the output signal SL MERGE via the level shifter 72.

The signal SLDRVON is set to “H” when the drivers DR(1) to DR(6) are driven, and otherwise to “L.” The signal SL_ERASE_MODE is set to “H” in the erase operation, and otherwise to “L.” Note that the transistors included in the

NAND circuit 71 and the level shifter 72 may be designed to have a lower breakdown voltage than the transistors Tr1 and Tr2.

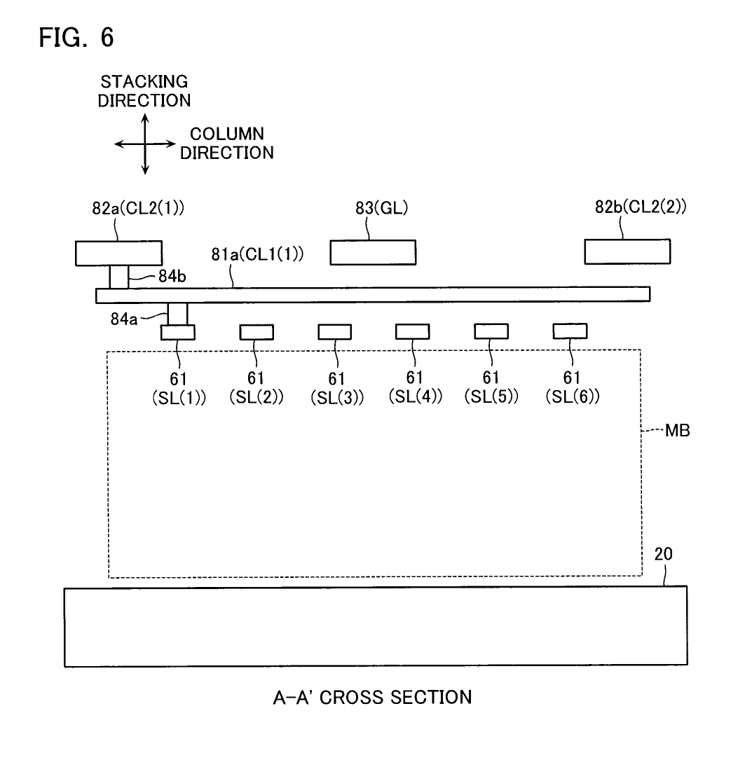

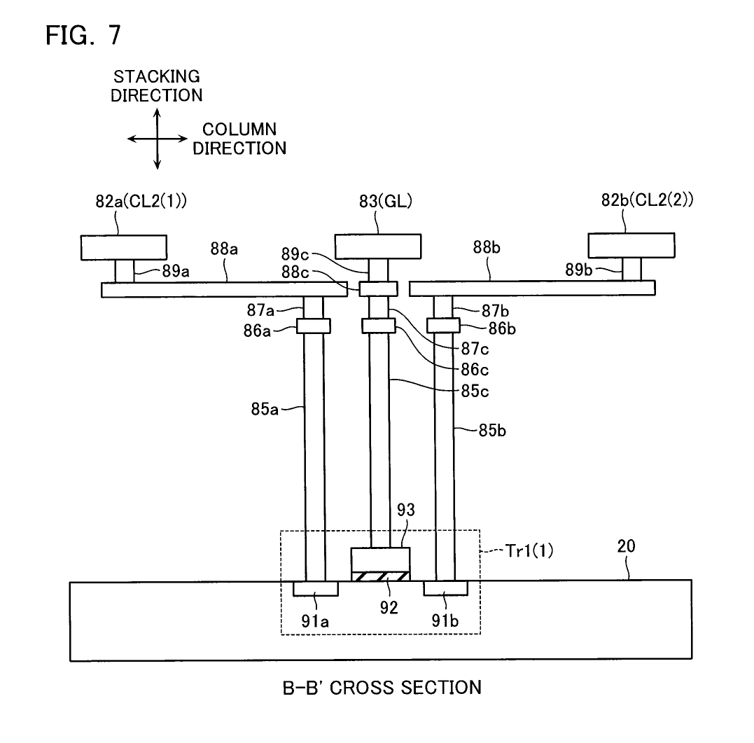

Referring now to FIG. 6 and FIG. 7, a description is given of the stacked structure providing the above source-lines SL(1) to SL(6), the first common wiring lines CL1(1) to CL1(6), the second common wiring lines CL2(1) to CL2(6), the gate line GL, and the transistors Tr1 and Tr2. FIG. 6 is a cross-sectional view along the A-A′ in FIG. 5. FIG. 7 is a cross-sectional view along the B-B′ in FIG. 5.

With reference to FIG. 6, in a layer above the source-line layer 61 (see FIG. 3) functioning as the source-line SL as described above, a first common wiring line layer 81a, second common wiring line layers 82a and 82b, and a gate conductive layer 83 are stacked via an interlayer insulating layer (not shown). The first common wiring line layer 81a functions as the first common wiring lines CL1 (1). The second common wiring line layers 82a and 82b function as the respective second common wiring lines CL2 (1) and CL2 (2).

The gate conductive layer 83 functions as the gate lines GL.

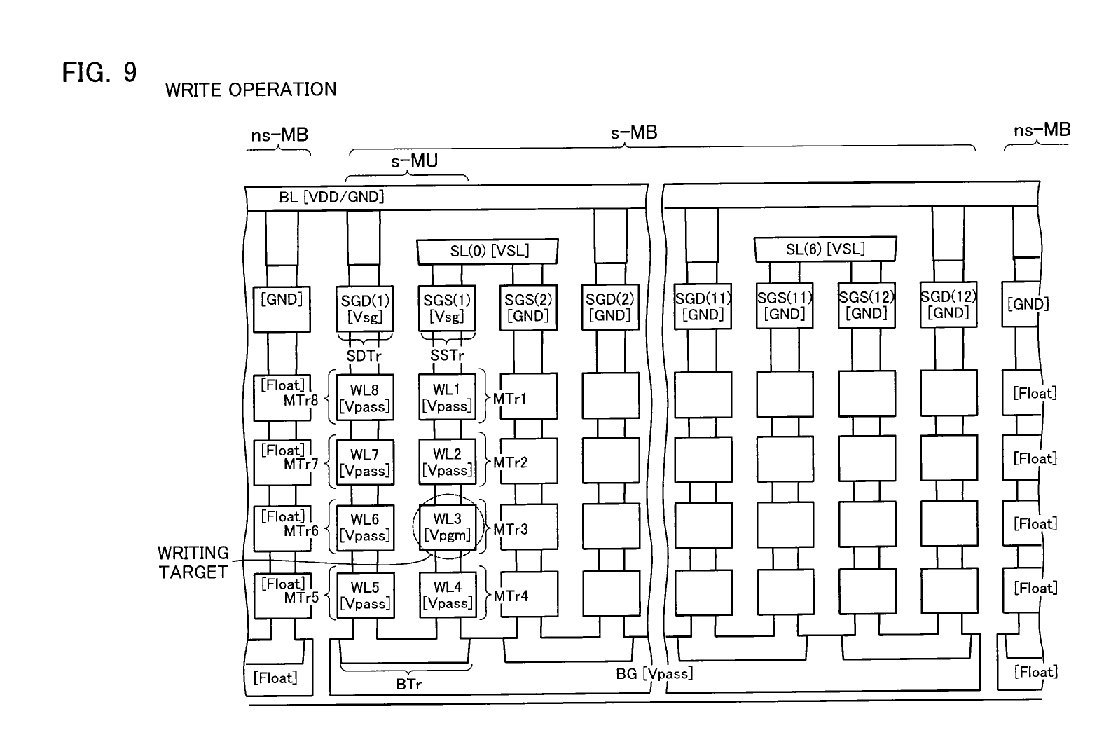

The first common wiring line layer 81a is provided in a layer above the source-line layer 61 and is formed extending in the column direction. The second common wiring line layers 82a and 82b and the gate conductive layer 83 are provided in a layer above the first common wiring line layer 81a, and are formed extending in the row direction (a direction perpendicular the plane of FIG. 9). The gate conductive layer 83 is positioned in the same layer as the second common wiring line layers 82a and 82b.

A top surface of the source-line layer 61 is connected to a bottom surface of the first common wiring line layer 81a via a plug layer 84a extending in the stacking direction. A top surface of the first common wiring line layer 81a is connected to a bottom surface of the second common wiring line layer 82a via a plug layer 84b extending in the stacking direction.

With reference to FIG. 7, the transistor Tr1 (1) includes a source/drain in a surface of the substrate 20. The transistor Tr1 (1) includes diffusion layers 91a and 91b, a gate insulating layer 92, and a gate electrode layer 93.

The diffusion layers 91a and 91b function as the respective source and drain of the transistor Tr1 (1). The diffusion layers 91a and 91b are formed at a predetermined pitch in the surface of the substrate 20. The gate insulating layer 92 is formed on the surface of the substrate 20 between the diffusion layer 91a and the diffusion layer 91b with a predetermined thickness. The gate electrode layer 93 functions as the gate of the transistor Tr1. The gate electrode layer 93 is formed on a top surface of the gate insulating layer 92.

The diffusion layers 91a and 91b are connected to the second common wiring line layers 82a and 82b via plug layers 85a and 85b, electrode layers 86a and 86b, plug layers 87a and 87b, electrode layers 88a and 88b, and plug layers 89a and 89b, respectively. The gate electrode layer 93 is connected to the gate conductive layer 83 via a plug layer 85c, an electrode layer 86c, a plug layer 87c, an electrode layer 88c, and a plug layer 89c. The electrode layers 86a to 86c are positioned in the same layer as the source-line layer 61. The electrode layers 88a to 88c are formed in the same layer as the first common wiring line layer 81a.

The above second common wiring line layers 82a and 82b are disposed at a larger pitch than the underlying first common wiring line layer 81a and source-line layers 61. Therefore, the transistor Tr1 (1) connecting the second common wiring line layers 82a and 82b with each other may be formed on the substrate 20 more easily than a transistor connecting the first common wiring line layers 81a (or the source-line layers 61) with each other.

### [Read Operation]

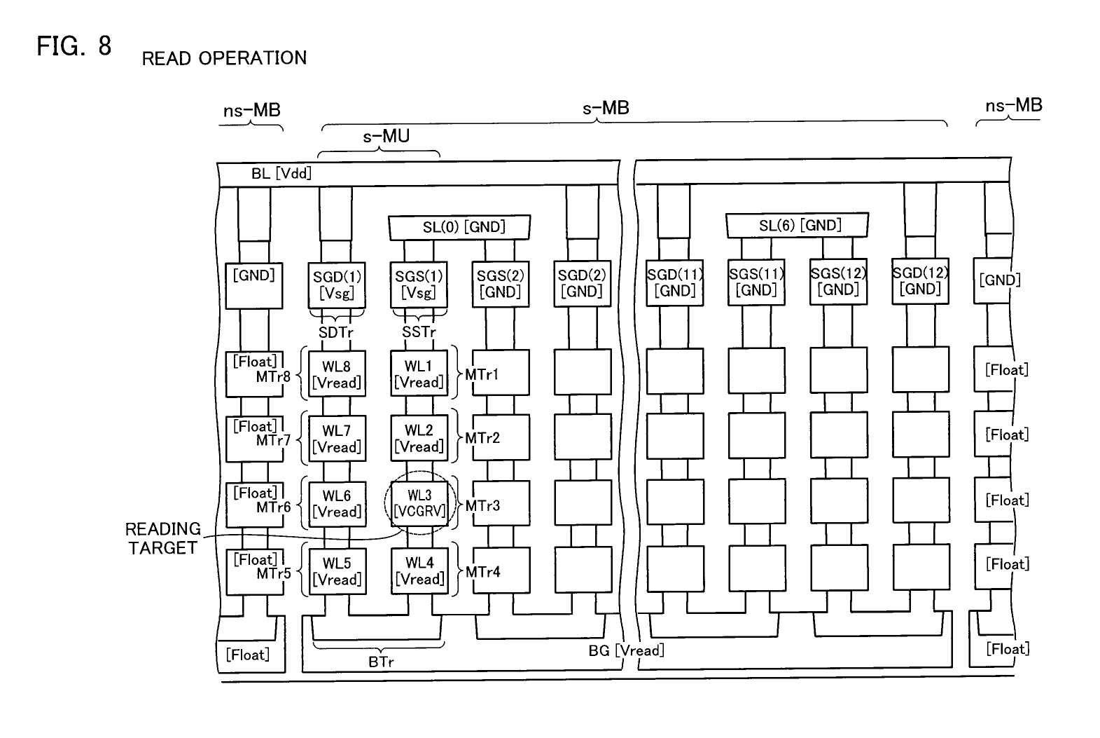

Referring now to FIG. 8, the read operation according to the first embodiment will be described. FIG. 8 shows a read operation that targets the memory transistor MTr3 included in a selected memory unit s-MU in a selected memory block s-MB. With reference to FIG. 8, in the read operation, all source-lines SL(1) to SL(6) in the memory block MB(1) are set to the same voltage. Note that it is assumed that the read operation herein also means a verify read operation.

With reference to FIG. 8, in the read operation, the bit-line BL is applied with the voltage VDD.

In the read operation, in the selected memory block s-MB, the source-line SL is grounded (GND). The word-lines WL1, WL2, WL4 to WL8, and the back gate line BG are applied with a read voltage Vread. The word-line WL3 is applied with a voltage VCGRV. The read voltage Vread is a voltage that may render the memory transistor MTr conductive regardless of data held in the memory transistor MTr. The voltage VCGRV is a voltage between two threshold voltage distributions that the memory transistor MTr may have.

Further, in the read operation, in the selected memory block s-MB, the source-side select gate line SGS(1) and the drain-side select gate line SGD(1) are applied with a voltage Vsg, and the source-side select gate lines SGS(2) to SGS(12) and the drain-side select gate lines SGD(2) to SGD(12) are applied with the ground (GND). Thus, only the source-side select transistor SSTr and the drain-side select transistor SDTr in the selected memory unit s-MU are rendered conductive.

The above voltage control causes current to flow from the bit-line BL to the source-line SL(1) depending on data held in the memory transistor MTr3. The current may be sensed to read data of the memory transistor MTr3.

In the above read operation, in the first embodiment, the transistors Tr1 and Tr2 shown in FIG. 5 commonly connect the source-lines SL(1) to SL(6). Therefore, the first embodiment may reduce, in the read operation, the wiring resistance of the source-line SL, thereby performing the read operation correctly.

### [Write Operation]

Referring now to FIG. 9, the write operation according to the first embodiment will be described. FIG. 9 shows a write operation that targets the memory transistor MTr3 included in the selected memory unit s-MU in the selected memory block s-MB. With reference to FIG. 9, in the write operation, all source-lines SL(1) to SL(6) in the selected memory block s-MB are set to the same voltage.

With reference to FIG. 9, in the write operation, the bit-line BL is applied with, depending on data to be written, the ground (GND) or the voltage VDD.

In the write operation, in the selected memory block s-MB, the source-line SL is applied with a voltage VSL. The word-lines WL1, WL2, and WL4 to WL8 and the back gate line BG are applied with a pass voltage Vpass. The word-line WL3 is applied with a programming voltage Vpgm. The pass voltage Vpass is a voltage that may render the memory transistor MTr conductive regardless of data held in the memory transistor MTr. The programming voltage Vpgm is a voltage to inject charge into the charge accumulation layer in the memory transistor MTr.

Further, in the write operation, in the selected memory block s-MB, the source-side select gate line SGS(1) and the drain-side select gate line SGD(1) are applied with the voltage Vsg, and the source-side select gate lines SGS(2) to SGS (12) and the drain-side select gate lines SGD (2) to SGS (12) are grounded (GND). Thus, in the selected memory unit s-MU, the source-side select transistor SSTr and the drain-side select transistor SDTr are rendered conductive.

The above voltage control causes the charge accumulation layer of the memory transistor MTr3 in the selected memory unit s-MU to be applied with a high voltage, thereby injecting charge into the charge accumulation layer. In other words, the memory transistor MTr3 in the selected memory unit s-MU is subjected to the write operation.

In the above write operation, in the first embodiment, the transistors Tr1 and Tr2 shown in FIG. 5 commonly connect the source-lines SL(1) to SL(6). Therefore, the first embodiment may reduce, in the write operation, the wiring resistance of the source-line SL.

### [Erase Operation]

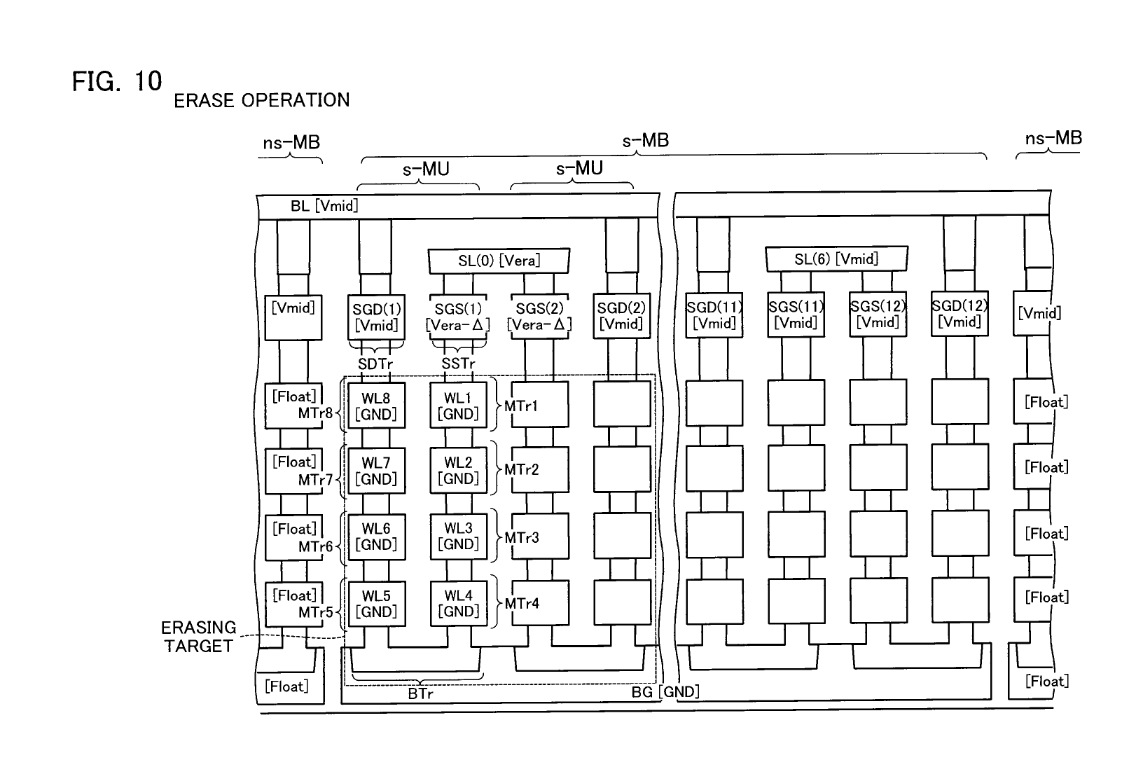

Referring now to FIG. 10, the erase operation according to the first embodiment will be described. FIG. 10 shows an erase operation that targets the selected memory unit s-MU in the selected memory block s-MB. FIG. 10 shows an example where the selected memory unit s-MU is connected to the source-line SL(1). With reference to FIG. 10, in the erase operation, in the selected memory block s-MB, the source-line SL (1) and the source-lines SL(2) to SL(6) are set to different voltages.

With reference to FIG. 10, in the erase operation, the bit-line BL is applied with a voltage Vmid.

In the erase operation, in the selected memory block s-MB, the source-line SL (1) is applied with a voltage Vera, and the source-lines SL(2) to SL(6) are applied with the voltage Vmid. The word-lines WL1 to WL8 and the back gate line BG are grounded (GND).

Further, in the erase operation, in the selected memory block s-MB, the source-side select gate lines SGS (1) and SGS (2) are applied with a voltage Vera-Δ, and the source-side select gate lines SGS (2) to SGS (12) and the drain-side select gate lines SGD (2) to SGD (12) are applied with the voltage Vmid.

The above voltage control causes a GIDL current in the vicinity of the gate of the source-side select transistor SSTr included in the selected memory unit s-MU. As a result, the voltages of the bodies of the memory transistors MTr1 to MTr8 included in the selected memory unit s-MU rise, thereby applying a high voltage to the charge accumulation layer. Thus, the memory transistors MTr1 to MTr8 included in the selected memory unit s-MU are subjected to the erase operation.

In the above erase operation, in the first embodiment, the transistors Tr1 and Tr2 shown in FIG. 5 render each of the source-lines SL (1) to SL (6) to be non-conductive. Thus, the first embodiment may control, in the erase operation, each of the source-lines SL(1) to SL(6) independently to selectively erase the selected memory unit s-MU.

### Second Embodiment

### [Connection Relationship of Source-Line SL]

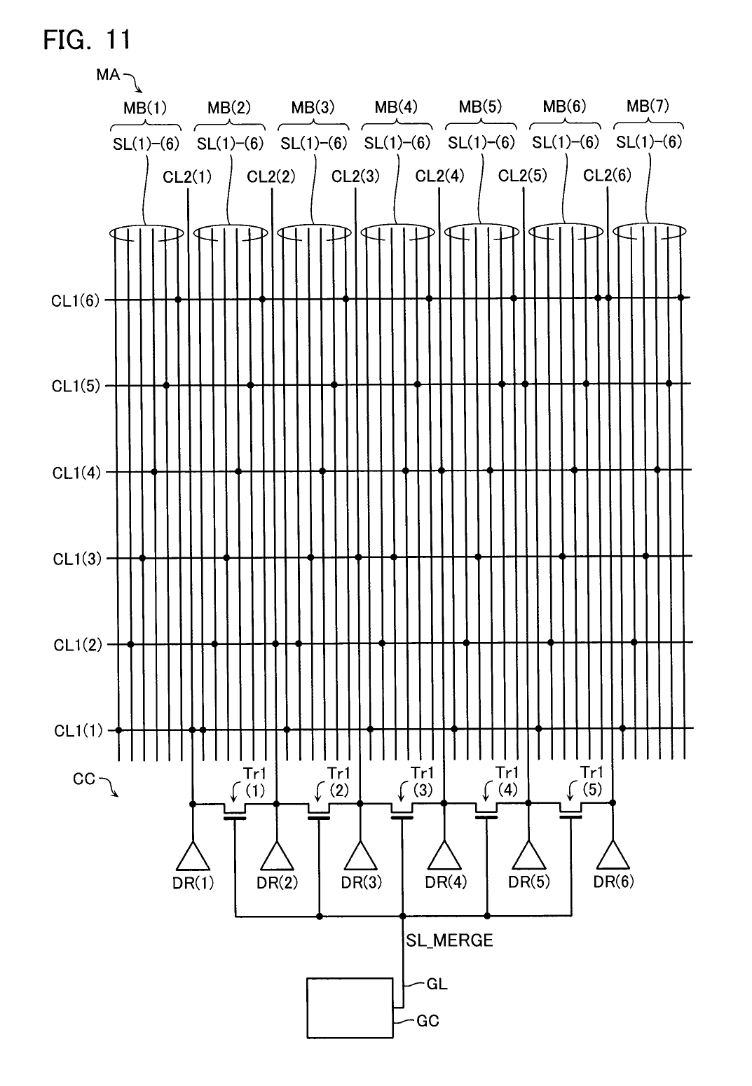

A non-volatile semiconductor memory device acccording to a second embodiment will now be described. The non-volatile semiconductor memory device according to the second embodiment includes the memory cell array MA like the first embodiment. With reference to FIG. 11, the second embodiment is different from the first embodiment in terms of the connection relationship between the source-lines SL(1) to SL(6) and the control circuit CC. Note that in the second embodiment, like components as those in the first embodiment are designated with like reference numerals and their detailed description is omitted here.

With reference to FIG. 11, the second embodiment does not include the transistor Tr2 unlike the first embodiment. Specifically, the second embodiment includes the transistors Tr1 (1) to Tr1 (5) only at the first ends of the second common wiring lines CL2 (1) to CL2 (6). In the second embodiment, like the first embodiment, the transistor Tr1 controls, in the write and read operations, the source-lines SL(1) to SL(6) by commonly connecting them, and controls, in the erase operation, each of the source-lines SL(1) to SL(6) independently. Thus, the second embodiment may provide a similar advantage to the first embodiment. The second embodiment may eliminate, compared to the first embodiment, the transistor Tr2. As a result, the second embodiment may provide a smaller circuit area than the first embodiment.

### Third Embodiment

### [Connection Relationship of Source-Line SL]

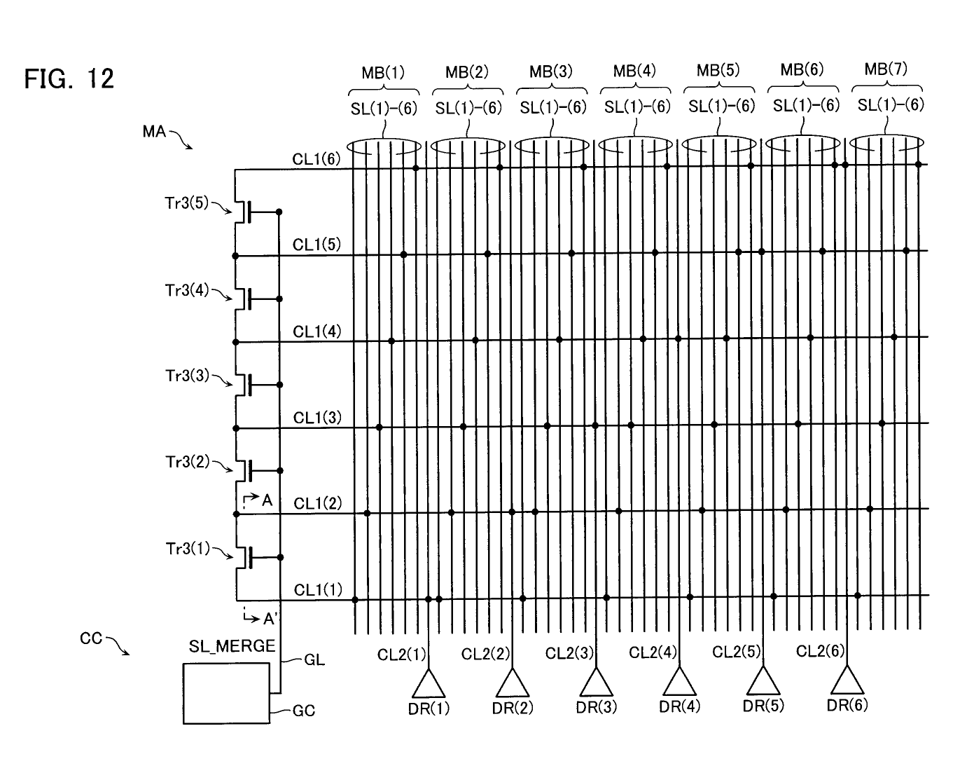

A non-volatile semiconductor memory device according to a third embodiment will now be described. The non-volatile semiconductor memory device according to the third embodiment includes the memory cell array MA like the first embodiment. With reference to FIG. 12, the third embodiment is different from the first embodiment in terms of the connection relationship between the source-lines SL(1) to SL(6) and the control circuit CC. Note that in the third embodiment, like components as those in the first embodiment are designated with like reference numerals and their description is omitted here.

In the third embodiment, the first common wiring line layers CL1(1) to CL1(6) are commonly connected to commonly connect the source-lines SL(1) to SL(6) unlike the first and second embodiments. With reference to FIG. 12, the third embodiment includes transistors Tr3(1) to Tr3(5) instead of the transistors Tr1 and Tr2 in the first embodiment. All transistors Tr3 (1) to Tr3 (5) may hereinafter be collectively described as a transistor Tr3.

The transistors Tr3 have a thicker gate oxide film than the source-side select transistors SSTr (the drain-side select transistors SDTr), and are designed to have a high breakdown voltage. The transistors Tr3 are provided at the respective first end sides of the first common wiring lines CL1(1) to CL1(6).

The transistor Tr3(1) is provided between the first common wiring line CL1(1) and the first common wiring line CL1(2). The transistor Tr3 (2) is provided between the first common wiring line CL1(2) and the first common wiring line CL1(3). The transistor Tr3 (3) is provided between the first common wiring line CL1(3) and the first common wiring line CL1(4). The transistor Tr3 (4) is provided between the first common wiring line CL1(4) and the first common wiring line CL1(5). The transistor Tr3 (5) is provided between the first common wiring line CL1(5) and the first common wiring line CL1(6).

Further, the gates of the transistors Tr3 are commonly supplied with a signal SL_MERGE from the gate control circuit GC via the gate line GL. In response to the signal, the transistors Tr3 are rendered conductive in the write and read operations and non-conductive in the erase operation. Therefore, the third embodiment may control, in the write and read operations, the source-lines SL(1) to SL(6) by commonly connecting them, and may control, in the erase operation, each of the source-lines SL(1) to SL(6) independently. Thus, the third embodiment may provide a similar advantage to the first embodiment.

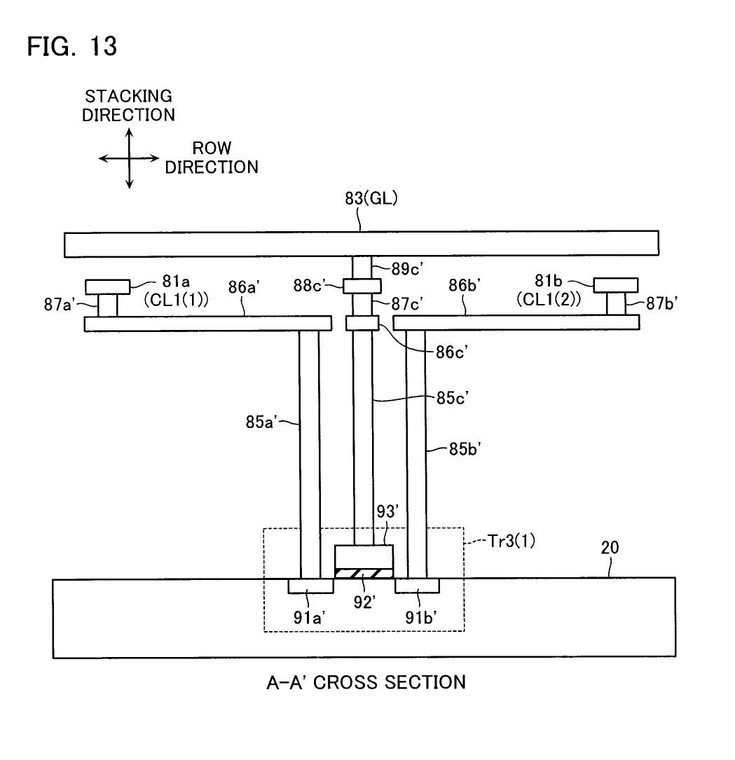

Referring now to FIG. 13, the stacked structure providing the above transistor Tr3 will be described. FIG. 13 is a cross-sectional view along the A-A′ in FIG. 12 .

With reference to FIG. 13, the transistor Tr3(1) includes a source/drain in the surface of the substrate 20. The transistor Tr3 (1) includes diffusion layers 91a′ and 91b′, a gate insulating layer 92′, and a gate electrode layer 93′.

The diffusion layers 91a′ and 91b′ function as the respective source and drain of the transistor Tr3 (1). The diffusion layers 91a′ and 91b′ are formed at a predetermined pitch in the surface of the substrate 20. The gate insulating layer 92′ is formed on the surface of the substrate 20 between the diffusion layer 91a′ and the diffusion layer 91b with a predetermined thickness. The gate electrode layer 93′ functions as the gate of the transistor Tr3 (1). The gate electrode layer 93′ is formed on a top surface of the gate insulating layer 92′.

The diffusion layers 91a′ and 91b′ are connected to the first common wiring line layers 81a and 81b (the first common wiring lines CL1 (1) and CL1 (2)) via plug layers 85a′ and 85b′, electrode layers 86a′ and 86b′, and plug layers 87a′ and 87b′, respectively. The gate electrode layer 93′ is connected to the gate conductive layer 83 (the gate line GL) via a plug layer 85c′, an electrode layer 86c′, a plug layer 87c′, an electrode layer 88c′, and a plug layer 89c′, respectively. The electrode layers 86a′ to 86c′ are positioned in the same layer as the source-line layer 61. The electrode layer 88c′ is formed in the same layer as the first common wiring line layers 81a and 81b.

The above first common wiring line layers 81a and 81b are disposed at a larger pitch than the source-line layer 61. Therefore, the transistor Tr3 (1) connecting the first common wiring line layers 81a and 81b with each other may be formed on the substrate 20 more easily than a transistor connecting the source-line layers 61 with each other.

### Fourth Embodiment

### [Connection Relationship of Source-Line SL]

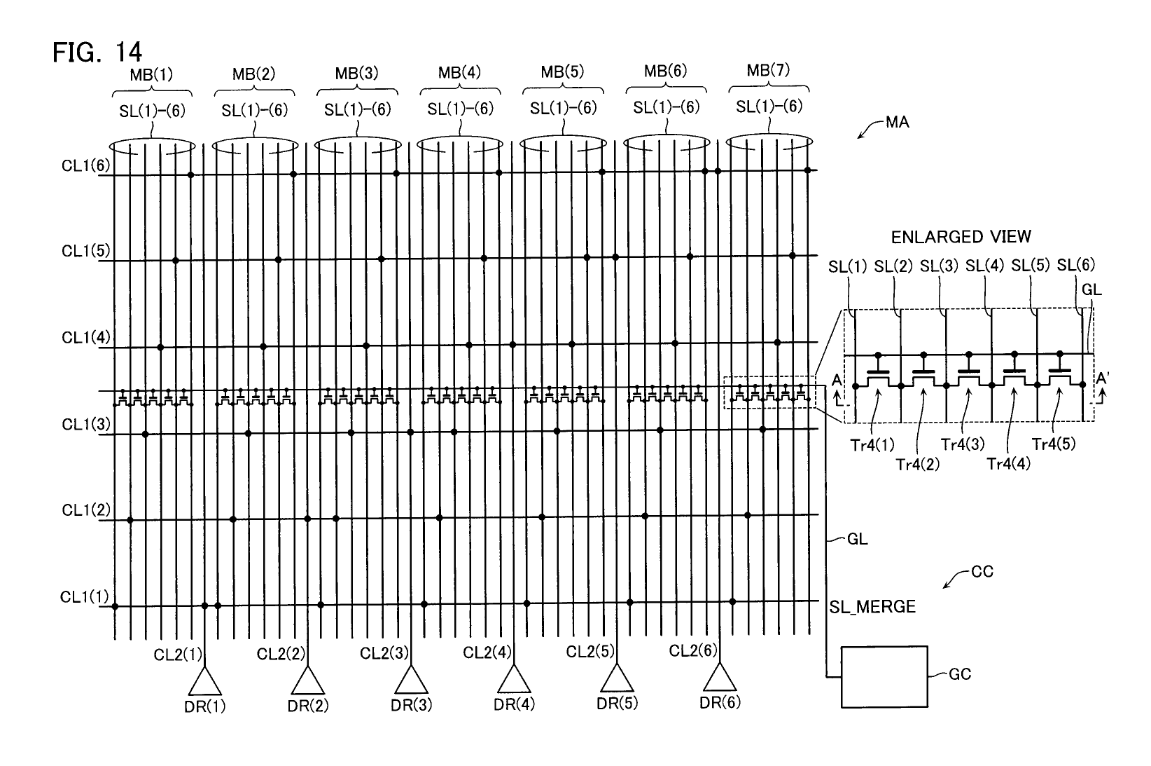

A non-volatile semiconductor memory device according to a fourth embodiment will now be described. The non-volatile semiconductor memory device according to the fourth embodiment includes the memory cell array MA like the first embodiment. With reference to FIG. 14, the fourth embodiment is different from the first embodiment in terms of the connection relationship between the source-lines SL (1) to SL(6) and the control circuit CC. Note that in the fourth embodiment, like components as those in the first embodiment are designated with like reference numerals and their description is omitted here.

The fourth embodiment commonly connects the source-lines SL(1) to SL(6) themselves unlike the first and second embodiments. With reference to FIG. 14, the fourth embodiment includes transistors Tr4 (1) to Tr4 (5) instead of the transistors Tr1 and Tr2 in the first embodiment. All transistors Tr4 (1) to Tr4 (5) may hereinafter be collectively described as a transistor Tr4.

The transistors Tr4 have a thicker gate oxide film than the source-side select transistors SSTr (the drain-side select transistors SDTr), and are designed to have a high breakdown voltage. The transistors Tr4 are formed in the region where the memory cell array MA is provided. The transistor Tr4(1) is provided between the source-line SL(1) and the source-line SL(2). The transistor Tr4(2) is provided between the source-line SL(2) and the source-line SL(3). The transistor Tr4(3) is provided between the source-line SL (3) and the source-line SL (4). The transistor Tr4 (4) is provided between the source-line SL(4) and the source-line SL (5). The transistor Tr4 (5) is provided between the source-line SL(5) and the source-line SL(6).

Further, gates of the transistors Tr4 are commonly supplied with a signal SL_MERGE from the gate control circuit GC via the gate line GL. In response to the signal, the transistors Tr4 are rendered conductive in the write and read operations and non-conductive in the erase operation. Therefore, the fourth embodiment may control, in the write and read operations, the source-lines SL(1) to SL(6) by commonly connecting them, and may control, in the erase operation, each of the source-lines SL(1) to SL(6) independently. Thus, the fourth embodiment may provide a similar advantage to the first embodiment.

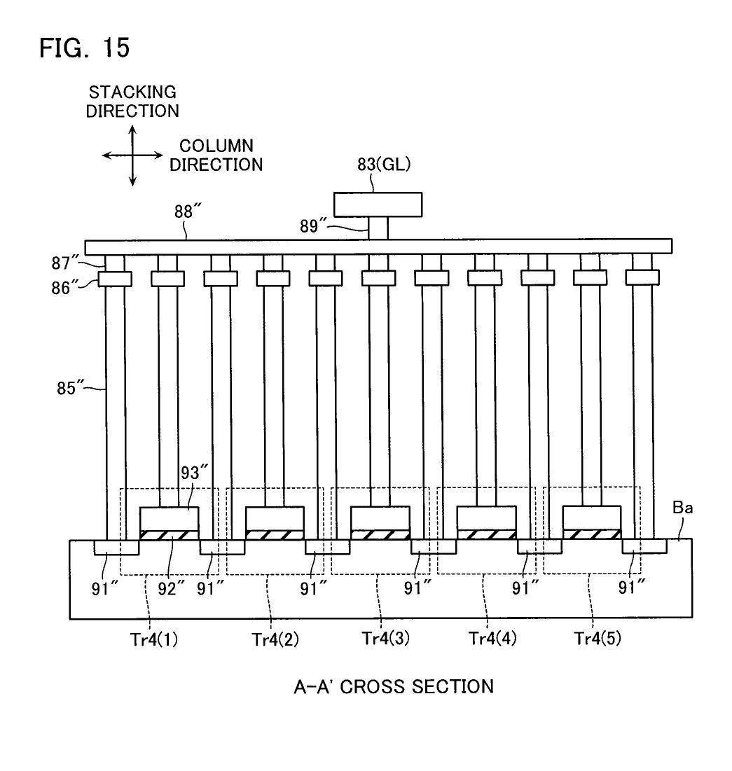

Referring now to FIG. 15, the stacked structure providing the above transistor Tr4 will be described. FIG. 15 is a cross-sectional view along the A-A′ in FIG. 14.

With reference to FIG. 15, the transistor Tr4 includes a source/drain in the surface of the substrate 20. The transistor Tr4 includes a diffusion layer 91″, a gate insulating layer 92″, and a gate electrode layer 93″.

The diffusion layer 91″ functions as a source or a drain of the transistor Tr4. The diffusion layer 91″ is shared by the adjacent transistors Tr4. The diffusion layer 91″ is formed in the surface of the substrate 20 at a predetermined pitch. The gate insulating layer 92″ is formed on the surface of the substrate 20 between the diffusion layers 91″ with a predetermined thickness. The gate electrode layer 93″ functions as the gate of the transistor Tr4. The gate electrode layer 93″ is formed on a top surface of the gate insulating layer 92″.

The diffusion layer 91″ is connected to the gate conductive layer 83 (the gate line GL) via a plug layer 85″, an electrode layer 86″, a plug layer 87″, an electrode layer 88″, and a plug layer 89″. The electrode layer 86″ is positioned in the same layer as the source-line layer 61. The electrode layer 88″ is positioned in the same layer as the first common wiring line layers 81a and 81b.

### Fifth Embodiment

### [Connection Relationship of Source-Line SL]

A non-volatile semiconductor memory device according to a fifth embodiment will now be described. The non-volatile semiconductor memory device according to the fifth embodiment includes the memory cell array MA like the first embodiment.

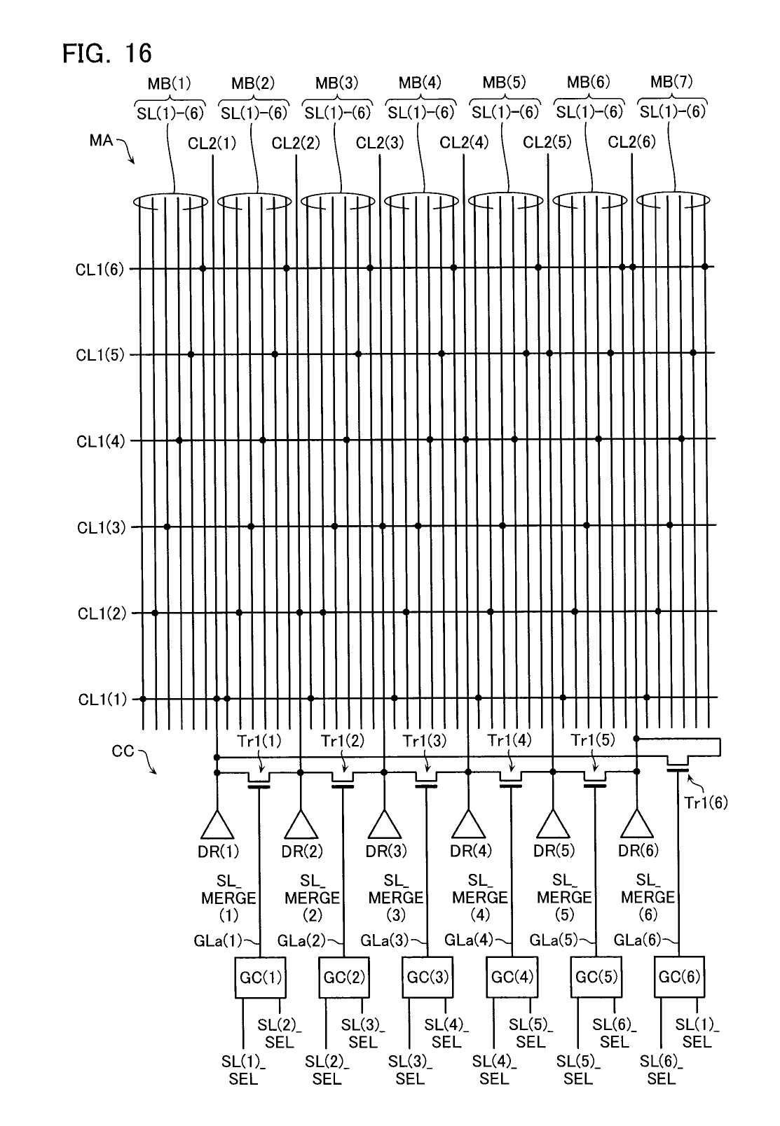

With reference to FIG. 16, the fifth embodiment is different from the first embodiment in terms of the connection relationship between the source-lines SL (1) to SL (6) and the control circuit CC. Note that in the fifth embodiment, like components as those in the first embodiment are designated with like reference numerals and their description is omitted here.

The fifth embodiment connects the second common wiring lines CL2(1) to CL2(6) with each other to connect the source-lines SL(1) to SL(6) like the second embodiment.

On the other hand, if the selected memory unit s-MU connected only to the source-line SL(1) is selectively subjected to the erase operation as shown in FIG. 10, the fifth embodiment commonly connects only the source-lines SL(2) to SL(6) with each other, and does not connect the source-line SL(1) with the source-lines SL(2) to SL(6). In other words, the fifth embodiment commonly connects, in the erase operation, only the non-selected source-lines SL(2) to SL(6) other than the selected source-line SL(1). In this regard, the fifth embodiment is different from the second embodiment. Thus, the fifth embodiment may reduce, even in the erase operation, the wiring resistance of the source-lines SL(2) to SL(6). In other words, the fifth embodiment may provide, in the erase operation, a lower wiring resistance of the source-line SL than the second embodiment.

To allow for the above control, the fifth embodiment includes, in addition to the transistors Tr1(1) to Tr1(5) in the first embodiment, a transistor Tr1(6) provided between the second common wiring line CL2(6) and the second common wiring line CL2(1). Further, in the fifth embodiment, gates of the transistors Tr1 (1) to Tr1 (6) are connected to the gate control circuits GC(1) to GC(6) via different gate lines GLa (1) to GLa (6), respectively. The gate control circuits GC (1) to GC(6) supply different signals SL_MERGE(1) to SL_MERGE(6) to the gates of the transistors Tr1 (1) to Tr1 (6), respectively. Thus, the transistors Tr1 (1) to Tr1 (6) may each be controlled independently.

The signals SL_MERGE(1) to SL_MERGE(6) are set to “L” when the respective drivers DR(1) to DR(6) are driven and the erase operation is performed and additionally the respective source-lines SL(1) to SL(6) are selected, and otherwise to “H.” Therefore, the transistors Tr1(1) to Tr1(6) are rendered non-conductive in the erase operation when the respective source-lines SL(1) to SL(6) are selected, and otherwise rendered conductive. In other word, in the erase operation, only the transistors Tr1(1) to Tr1(6) connected to the selected source-lines SL are rendered non-conductive, and the transistors Tr1(1) to Tr1(6) connected to the non-selected source-lines SL are rendered conductive.

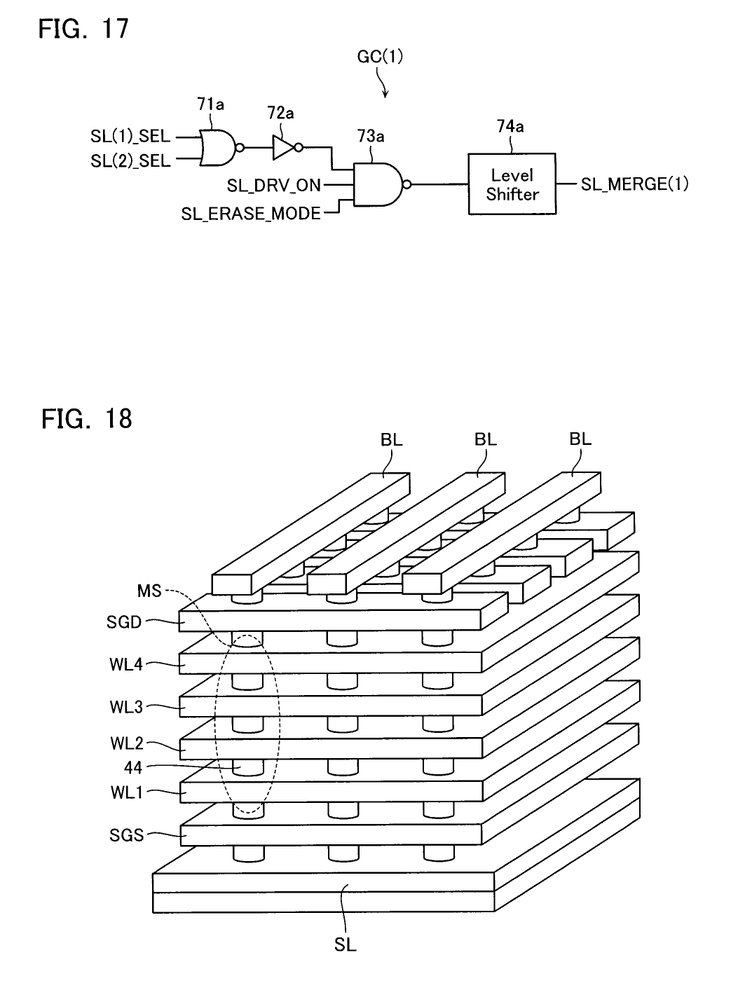

Referring now to FIG. 17, the configuration of the gate control circuit GC(1) will be described. With reference to FIG. 17, the gate control circuit GC (1) includes a NOR circuit 71a, an inverter 72a, a NAND circuit 73a, and a level shifter 74a.

The NOR circuit 71a is supplied with a signal SL(1)_SEL at a first end input terminal, and is supplied with a signal SL(2)_SEL at a second end input terminal. The NOR circuit 71a supplies, in response to the supplied signal, an output signal to a first input terminal of the NADN circuit 73a via the inverter 72a. The signals SL(1)_SEL and SL(2)_SEL are set to “H” when the respective source-lines SL(1) and SL(2) are selected, and otherwise to “L.”

The NAND circuit 73a is supplied with the signal SL_DRV_ON at a second input terminal and is supplied with the signal SL_ERASE_MODE at a third input terminal. The NAND circuit 73a outputs, in response to the supplied signal, an output signal SL-MERGE(1) via the level shifter 74a. Note that the transistors included in the NOR circuit 71a, the inverter 72a, the NAND circuit 73a, and the level shifter 74a may be designed to have a lower breakdown voltage than the transistor Tr1.

The gate control circuits GC(2) to GC(6) have generally the same configuration as the gate control circuit GC (1) shown in FIG. 17, and thus their description is omitted here. Note, however, that with reference to FIG. 16, the gate control circuits GC(2) to GC(6) are supplied with the signals SL(2)_SEL to signal SL(6)_SEL, and output, in response to these signals, the signals SL_MERGE(1) to SL_MERGE(6), respectively. The signals SL(3)_SEL to SL(6)_SEL are set to “H” when the respective source-lines SL(3) to SL(6) are selected, and otherwise to “L.”

In the above configuration, the fifth embodiment may commonly connect, in the erase operation, the non-selected source-lines SL other than the selected source-lines SL. In other words, the fifth embodiment may provide, in the erase operation, a lower wiring resistance of the source-line SL than the second embodiment.

### Other Embodiments

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

For example, the configuration in the fifth embodiment is applicable to the first to fourth embodiments. For example, in the above embodiments, the memory semiconductor layer 44 functioning as the bodies of the memory strings MS is formed in a U shape when viewed in the row direction. With reference to FIG. 18, however, the memory semiconductor layer 44 may be formed in an I shape when viewed in the row direction.

What is claimed is:

1. A non-volatile semiconductor memory device comprising:
a plurality of memory strings each including a plurality of stacked memory transistors;
a plurality of memory blocks each including the plurality of memory strings;
a plurality of source-lines each connected to the respective memory strings; and
a control circuit configured to output signals to a switch circuit depending on the types of operations for the memory transistors, the switch circuit being capable of connecting the plurality of source-lines electrically and commonly depending on the signals.

2. The non-volatile semiconductor memory device according to claim 1, further comprising a plurality of common wiring lines commonly connecting the source-lines among the memory blocks, wherein
the switch circuit includes a plurality of transistors provided at least between the common wiring lines or between the source-lines.

3. The non-volatile semiconductor memory device according to claim 2, wherein
in the read operation and the write operation for the memory transistors, the transistors are rendered conductive by applying a first voltage to a plurality of gates of the plurality of transistors, and
in the erase operation for the memory transistors, the transistors are rendered non-conductive by applying a second voltage lower than the first voltage to a plurality of gates of the plurality of transistors.

4. The non-volatile semiconductor memory device according to claim 2, wherein
in the read operation and the write operation for the memory transistors, the transistors are rendered conductive by applying a first voltage to a plurality of gates of the plurality of transistors, and
in the erase operation for the memory transistors, only selected ones of the transistors are rendered non-conductive by applying a second voltage lower than the first voltage to gates of the selected ones of the transistors, and the other non-selected ones of the transistors are rendered conductive by applying the first voltage to gates of the other non-selected ones of the transistors.

5. The non-volatile semiconductor memory device according to claim 2, wherein
the control circuit comprises drivers supplying voltages to the source-lines via the common wiring lines,
the common wiring lines comprise a plurality of first common wiring lines commonly connecting the source-lines among the memory blocks and a plurality of second common wiring lines connecting the first common wiring lines with the respective drivers,
the source-lines are provided in a layer above the first semiconductor layer and extend in a first direction parallel to the substrate,
the first common wiring lines are provided in a layer above the source-lines and extend in a second direction parallel to the substrate, and
the second common wiring lines are provided in a layer above the first wiring lines and extend in the first direction.

6. The non-volatile semiconductor memory device according to claim 5, wherein
the transistors are provided between the source-lines.

7. The non-volatile semiconductor memory device according to claim 5, wherein
the transistors are provided between the first common wiring lines.

8. The non-volatile semiconductor memory device according to claim 5, wherein
the transistors are provided between the second common wiring lines.

9. The non-volatile semiconductor memory device according to claim 8, wherein
more than one of the transistors are provided to each of the second common wiring lines.

10. The non-volatile semiconductor memory device according to claim 1, further comprising:
first select transistors connected between respective first ends of the memory strings and the respective source-lines; and
second select transistors connected to respective second ends of the memory strings.

11. The non-volatile semiconductor memory device according to claim 10, wherein
each of the memory strings comprising:
a first semiconductor layer comprising a columnar portion extending in a direction perpendicular to a substrate, the first semiconductor layer functioning as a body of a memory transistor;
a charge accumulation layer surrounding a side surface of the columnar portion; and
a first conductive layer surrounding a side surface of the charge accumulation layer, the first conductive layer functioning as a gate of the memory transistor.

12. The non-volatile semiconductor memory device according to claim 11, wherein
each of the first select transistors comprises:
a second semiconductor layer extending in a direction perpendicular to the substrate, the second semiconductor layer functioning as a body of a first select transistor;
a first gate insulating layer surrounding a side surface of the second semiconductor layer; and
a second conductive layer surrounding a side surface of the first gate insulating layer, the second conductive layer functioning as a gate of the first select transistor.

13. The non-volatile semiconductor memory device according to claim 12, wherein
each of the second select transistors comprising:
a third semiconductor layer extending in a direction perpendicular to the substrate, the third semiconductor layer functioning as a body of a second select transistor;
a second gate insulating layer surrounding a side surface of the third semiconductor layer; and
a third conductive layer surrounding a side surface of the second gate insulating layer, the third conductive layer functioning as a gate of the second select transistor.

14. The non-volatile semiconductor memory device according to claim 11, wherein
the first semiconductor layer comprises a joining portion joining the lower ends of a pair of the columnar portions.

15. The non-volatile semiconductor memory device according to claim 11, wherein
the first conductive layer is formed in a comb teeth shape.

16. The non-volatile semiconductor memory device according to claim 10, wherein
in the read operation, the control circuit renders the first select transistors and the second select transistors conductive, supplies a third voltage to the gate of a non-selected memory transistor to render the non-selected memory transistor conductive, and supplies a fourth voltage lower than the third voltage to a gate of a selected memory transistor.

17. The non-volatile semiconductor memory device according to claim 10, wherein
in the write operation, the control circuit renders the first select transistors, the second select transistors, and a non-selected memory transistor conductive, and supplies a fifth voltage to a gate of a selected memory transistor, and wherein
the fifth voltage is a voltage for injecting charge into the charge accumulation layer.

18. The non-volatile semiconductor memory device according to claim 10, wherein
in the erase operation, the control circuit supplies a sixth voltage to the source-lines, supplies a seventh voltage to the gates of the first select transistors, and grounds the gates of the memory transistors, and wherein a potential difference between the seventh voltage and the sixth voltage causes a GIDL current.
